(19) United States
(12) Patent Application Publication
(10) Pub. No.: US 2026/0329029 A1
(43) Pub. Date: Oct. 22, 2026

(54) SEMICONDUCTOR PACKAGE INCLUDING PHOTONIC INTEGRATED CIRCUIT AND MANUFACTURING METHOD THEREOF

(71) Applicant: SAMSUNG ELECTRONICS CO., LTD., Suwon-si (KR)

(72) Inventors: Youngja KIM, Suwon-si (KR); Junghyun Roh, Suwon-si (KR)

(73) Assignee: SAMSUNG ELECTRONICS CO., LTD., Suwon-si (KR)

(21) Appl. No.: 19/391,239

(22) Filed: Nov. 17, 2025

(30) Foreign Application Priority Data
Apr. 21, 2025 (KR) 10-2025-0051905

(51) Int. Cl. G02B 6/42; G02B 6/122; H10D 80/30; H10F 39/95; H10H 29/24; H10W 90/00; G02B 6/12; H10W 70/60; H10W 74/15

(52) U.S. Cl. CPC G02B 6/4212; G02B 6/122; G02B 6/4206; G02B 6/4239; G02B 6/4244; H10D 80/30; H10F 39/95; H10H 29/24; H10W 90/00; G02B 2006/12147; H10W 70/611; H10W 74/15; H10W 90/401; H10W 90/724; H10W 90/734; H10W 90/792

(57) ABSTRACT

A semiconductor package may include: a photonic integrated circuit (PIC) chip; an electronic integrated circuit (EIC) chip on the PIC chip in a first direction; an optical path block adjacent to the EIC chip in a second direction intersecting the first direction; and an adhesive film that attaches the optical path block to the PIC chip in the first direction. The adhesive film may include at least one opening that is configured to pass light.

### CROSS-REFERENCE TO RELATED APPLICATION

This application is based on and claims priority under 35 U.S.C. §119 to Korean Patent Application No. 10-2025-0051905, filed on Apr. 21, 2025, in the Korean Intellectual Property Office, the disclosure of which is incorporated by reference herein in its entirety.

### BACKGROUND

### 1. Field

Some embodiments of the present disclosure relate to a semiconductor package, and more particularly, to a semiconductor package including a photonic integrated circuit (PIC), and a manufacturing method thereof.

### 2. Description of Background Art

With the development of the electronics industry, the demand for high-performance, high-speed, and miniaturized electronic products is increasing. Following this trend, the need for miniaturized and multi-functional semiconductor chips used in electronic components is increasing. In addition, in the field of semiconductor packages, the size of semiconductor packages is also being reduced based on small semiconductor chips. In addition, due to the demand for improved performance and reduced form factor of semiconductor packages, semiconductor package structures are moving toward multi-chip integration structures. The multi-chip integration refers to integrating multiple functional chips together into a single semiconductor package. Recently, PIC chips and electronic integrated circuit (EIC) chips are being integrated together into a single semiconductor package.

### SUMMARY

According to some embodiments of the present disclosure, a semiconductor package including a photonic integrated circuit (PIC) chip and an electronic integrated circuit (EIC) chip with improved reliability, and a manufacturing method thereof, may be provided.

According to some embodiments of the present disclosure, a semiconductor package may include: a photonic integrated circuit (PIC) chip; an electronic integrated circuit (EIC) chip on the PIC chip in a first direction; an optical path block adjacent to the EIC chip in a second direction intersecting the first direction; and an adhesive film that attaches the optical path block to the PIC chip in the first direction, wherein the adhesive film includes at least one opening that is configured to pass light.

According to some embodiments of the present disclosure, a semiconductor package may include: a photonic integrated circuit (PIC) chip including: a substrate including a through electrode; and an active layer on the substrate in a first direction, the active layer including an optical coupler; an electronic integrated circuit (EIC) chip on the PIC chip in the first direction, and overlapping with the through electrode in the first direction an optical path block adjacent to the EIC chip in a second direction intersecting the first direction, and overlapping with the optical coupler in the first direction; an adhesive film that attaches the optical path block to the PIC chip in the first direction; a sealant on the PIC chip and at least partially surrounding the EIC chip and the optical path block; and a connection terminal on a bottom surface of the PIC chip, wherein the adhesive film includes a ring shape on an outer portion of a bottom surface of the optical path block.

According to some embodiments of the present disclosure, a semiconductor package may include: a package substrate; an optical engine unit (OEU) package on the package substrate in a first direction; a logic device on the package substrate in the first direction, and adjacent to the OEU package; and a memory device adjacent to the logic device, and on the package substrate in the first direction, wherein the OEU package includes: a photonic integrated circuit (PIC) chip; an electronic integrated circuit (EIC) chip on the PIC chip in the first direction; an optical path block adjacent to the EIC chip in a second direction intersecting the first direction; and an adhesive film that attaches the optical path block to the PIC chip in the first direction, and wherein the adhesive film includes at least one opening that is configured to pass light.

Aspects of embodiments of the present disclosure are not limited to the mentioned above, and other aspects of embodiments of the present disclosure may be clearly understood by those skilled in the art from the description below.

### BRIEF DESCRIPTION OF DRAWINGS

Embodiments will be more clearly understood from the following detailed description taken in conjunction with the accompanying drawings in which:

FIG. 1 is a plan view of a semiconductor package according to an embodiment;

FIG. 2A is a first cross-sectional view of the semiconductor package of FIG. 1;

FIG. 2B is a second cross-sectional view of the semiconductor package of FIG. 1;

FIG. 3 is an enlarged cross-sectional view of an optical engine unit (OEU) package in the semiconductor package of FIG. 2B;

FIGS. 4A, 4B and 4C, are perspective views of a structure in which an optical path block is coupled to a photonic integrated circuit (PIC) chip, in the OEU package of FIG. 3;

FIGS. 5A, 5B, 5C, 5D and 5E, are perspective views and cross-sectional views of various structures of the optical path block, in the OEU package of FIG. 3;

FIGS. 6A, 6B, 6C, 6D, 6E and 6F, are perspective views of various structures of an adhesive film in the OEU package of FIG. 3;

FIG. 7A is a plan view of the semiconductor package according to an embodiment;

FIG. 7B is a cross-sectional view of the semiconductor package of FIG. 7A according to an embodiment;

FIGS. 8A, 8B, 8C and 8D, are schematic cross-sectional views illustrating a process of a method of manufacturing the semiconductor package, according to an embodiment; and

FIGS. 9A, 9B, 9C, 9D and 9E are cross-sectional views illustrating a process of manufacturing the OEU package in more detail, in the operation of mounting the OEU package of FIG. 8A.

### DETAILED DESCRIPTION

Hereinafter, non-limiting example embodiments of the present disclosure are described in detail with reference to the accompanying drawings. The same reference numerals are used for the same components in the drawings, and redundant descriptions thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

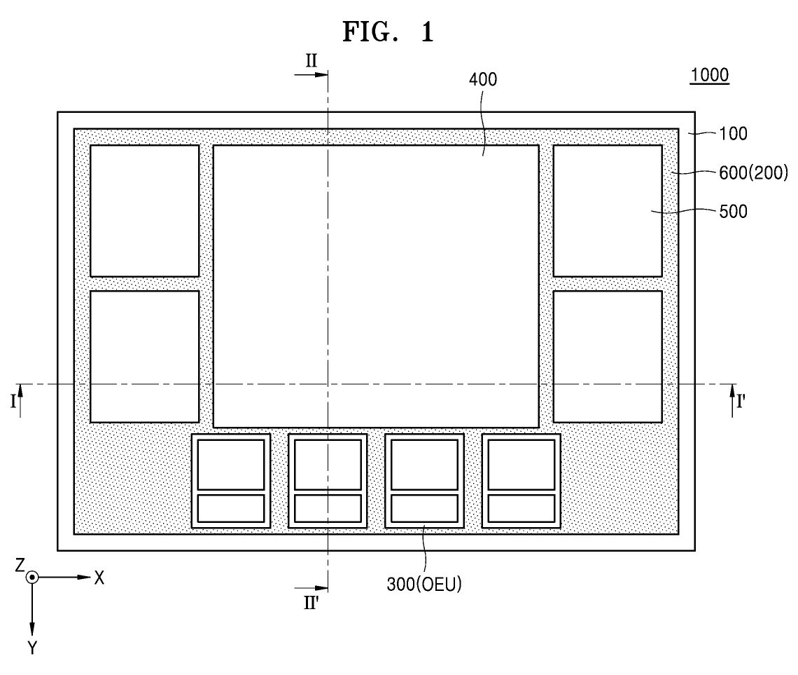

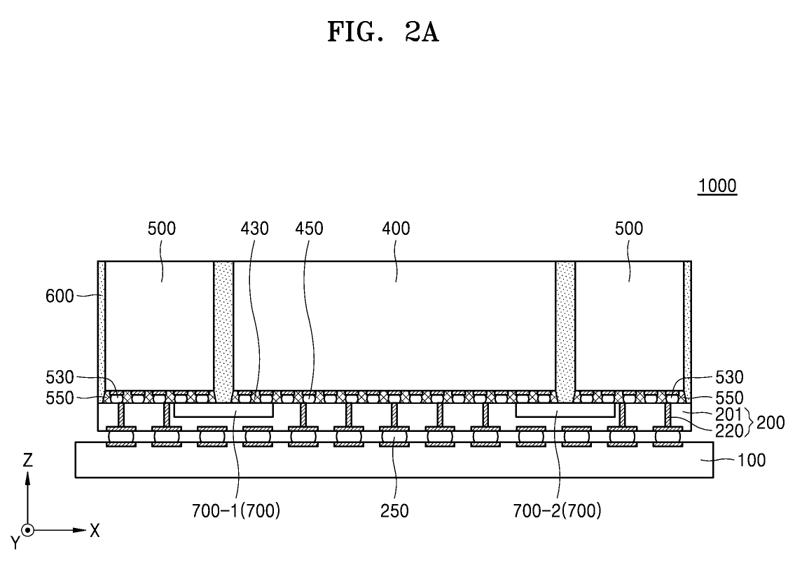

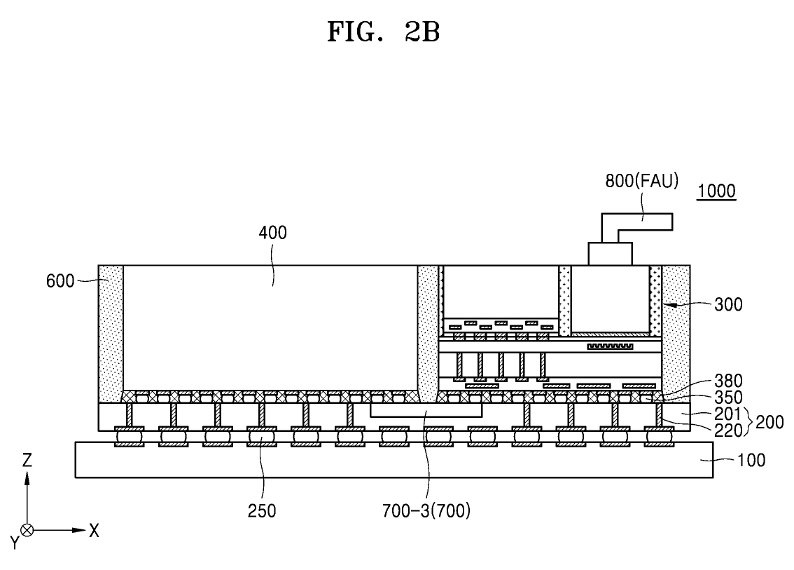

FIG. 1 is a plan view of a semiconductor package according to an embodiment. FIGS. 2A and 2B are cross-sectional views of the semiconductor package of FIG. 1, wherein FIG. 2A is a cross-sectional view of the semiconductor package of FIG. 1 taken along a line I-I′ and FIG. 2B is a cross-sectional view of the semiconductor package of FIG. 1 taken along a line II-II′.

Referring to FIGS. 1-2B, a semiconductor package 1000 may include a package substrate 100, an interposer 200, optical engine unit (OEU) packages 300, a first semiconductor device 400, second semiconductor devices 500, and a sealant 600. The semiconductor package 1000 of an embodiment may include, for example, a semiconductor package that communicates with an external device through optical signals.

Hereinafter, unless otherwise specified, directions parallel to a top surface of the package substrate 100 are defined as an X direction and a Y direction, and a direction perpendicular to the top surface of the package substrate 100 is defined as a Z direction. The X direction and the Y direction may intersect (e.g., be perpendicular to) each other, and the Z direction may intersect (e.g., be perpendicular to) the X direction and the Y direction.

The package substrate 100 may include a substrate on which the interposer 200 is mounted. In some embodiments, the package substrate 100 may include a motherboard or a system substrate on which various types of semiconductor chips and packages are mounted. For example, the package substrate 100 may receive electrical signals from the interposer 200 and transmit the electrical signals to the external device or may transmit the electrical signals, power, and the like from the external device to the interposer 200.

The package substrate 100 may include, for example, a ceramic substrate, a printed circuit board (PCB), an organic substrate, an interposer substrate, and the like. In some embodiments, the package substrate 100 may include an active wafer, such as a silicon wafer. In the semiconductor package 1000 of an embodiment, the package substrate 100 may include a PCB. However, the package substrate 100 is not limited to a PCB.

The package substrate 100 may include a substrate body layer, a protective layer, and at least one substrate pad. The substrate body layer may constitute the body of the package substrate 100 and may include a wiring layer therein. For example, when the package substrate 100 is a PCB, the substrate body layer may include a core layer and a wiring layer.

The core layer may include, for example, a resin and a glass fiber, such as flame retardant 4 (FR-4). In addition, the core layer may also include a bismaleimide-triazine (BT) resin, a polycarbonate (PC) resin, a build-up film, such as Ajinomoto build-up film (ABF), or other laminate resins.

The wiring layer may be divided into an upper wiring layer and a lower wiring layer with respect to the core layer. The upper wiring layer and the lower wiring layer may each include multilayered wires. In the semiconductor package 1000 of an embodiment, the wiring layer of the package substrate 100 may include 8 to 14 layers of wires. However, the number of layers of wires in the wiring layer is not limited to the above numerical range.

In some embodiments, the core layer may be omitted. For example, in some embodiments, the package substrate 100 may include a redistribution substrate. In such a case, the substrate body layer may not include a separate core layer and may include an interlayer insulating layer of a photo-imageable dielectric (PID) resin and multilayered wires.

The protective layer may include an upper protective layer on the top surface of the substrate body layer and a lower protective layer on the bottom surface of the substrate body layer. The protective layer may include, for example, a solder resist (SR). However, the material of the protective layer is not limited to SR.

The at least one substrate pad may include at least one upper substrate pad at (e.g., in or on) the top surface of the substrate body layer and at least one lower substrate pad at (e.g., in or on) the bottom surface of the substrate body layer. The upper substrate pad may pass through the upper protective layer. In addition, the lower substrate pad may pass through the lower protective layer. The upper substrate pad and the lower substrate pad may each be connected to the wires of the substrate body layer.

In addition, first connection terminals 250 may be disposed on the upper substrate pads, and external connection terminals may be disposed on the lower substrate pads. In FIGS. 2A and 2B, the external connection terminals are omitted. In general, the external connection terminals may connect the semiconductor package 1000 to a package substrate of an external system or a main board of an electronic device, such as a mobile device. The external connection terminals may include a conductive material such as, for example, at least one from among solder, tin (Sn), silver (Ag), copper (Cu), and aluminum (Al). However, the material of the external connection terminals is not limited to the above-described materials.

The interposer 200 may be mounted on the package substrate 100 by the first connection terminals 250. The OEU packages 300, the first semiconductor device 400, and the second semiconductor devices 500 may be mounted on the package substrate 100 by the interposer 200. For example, the OEU packages 300, the first semiconductor device 400, and the second semiconductor devices 500 may be mounted on the interposer 200 and may be electrically connected to the package substrate 100 by the interposer 200. That is, the interposer 200 may be arranged between the package substrate 100 and the OEU packages 300 and between the package substrate 100 and the semiconductor devices (e.g., the first semiconductor device 400 and the second semiconductor devices 500).

The interposer 200 may mediate signal transmission between the first semiconductor device 400 and the second semiconductor devices 500, signal transmission between the semiconductor devices (e.g., the first semiconductor device 400 and the second semiconductor devices 500) and the OEU packages 300, and signal, power, or ground transmission between the package substrate 100 and the OEU packages 300, the first semiconductor device 400, or the second semiconductor devices 500. In the semiconductor package 1000 of an embodiment, the interposer 200 may include a 2.3D interposer. Accordingly, the interposer 200 may include a silicon (Si)-bridge 700 therein. However, in the semiconductor package 1000 of an embodiment, the interposer 200 is not limited to a 2.3D interposer. For example, the semiconductor package 1000 of an embodiment may include a 2.5D interposer such as, for example, a Si-interposer. In such a case, the Si-bridge 700 may be omitted.

For reference, the interposer may include a 2.5D interposer and a 2.3D interposer. The 2.5D interposer may refer to the Si-interposer and may include at least one through silicon via (TSV) therein. On the other hand, the 2.3D interposer may refer to an organic or inorganic interposer that does not include the TSV. In the case of the organic interposer, polyimide (PI), benzocyclobutene (BCB), and polybenzoxazole (PBO) may be used as the body layer. In the case of the inorganic interposer, ceramic or glass may be used as the body layer. On the other hand, the 2.3D interposer may be referred to as a panel level package (PLP) interposer or a redistribution layer (RDL) interposer. For example, the Si-bridge may be included in the 2.3D interposer. The 2.3D interposer may include at least one through electrode. Depending on the material of the body layer, the through electrode may be referred to as a through glass via (TGV) or a through dielectric via (TDV).

The interposer 200 may include a body layer 201 and through electrodes 220. In some embodiments, the interposer 200 may include an RDL arranged in at least one from among an upper portion and a lower portion of the body layer 201. The body layer 201 may include an organic material or an inorganic material, as described above.

The through electrodes 220 may extend through the body layer 201. The through electrodes 220 may electrically connect the upper semiconductor devices (e.g., the first semiconductor device 400 and the second semiconductor devices 500) to the package substrate 100 and electrically connect the OEU packages 300 to the package substrate 100. The through electrodes 220 may include, for example, Cu. However, the material of the through electrodes 220 is not limited to Cu. The through electrodes 220 may be formed through electroplating using a seed metal. The seed metal may include various metal materials, such as Cu, titanium (Ti), tantalum (Ta), titanium nitride (TiN), and tantalum nitride (TaN).

On the other hand, when the RDL is disposed on the top surface and/or the bottom surface of the body layer 201, the RDL may include an interlayer insulating layer and redistribution lines. The interlayer insulating layer may include an insulating material, such as a PID or a photo-imageable polyimide (PIP) resin, and may further include an inorganic filler. The redistribution lines may be arranged in multiple layers in the interlayer insulating layer. The redistribution lines arranged in the other layers may be connected to each other by vertical vias. The redistribution lines may be connected to the through electrodes 220. In addition, the redistribution lines may be connected to the upper semiconductor devices (e.g., the first semiconductor device 400 and the second semiconductor devices 500) and the OEU packages 300 or may be connected to the package substrate 100.

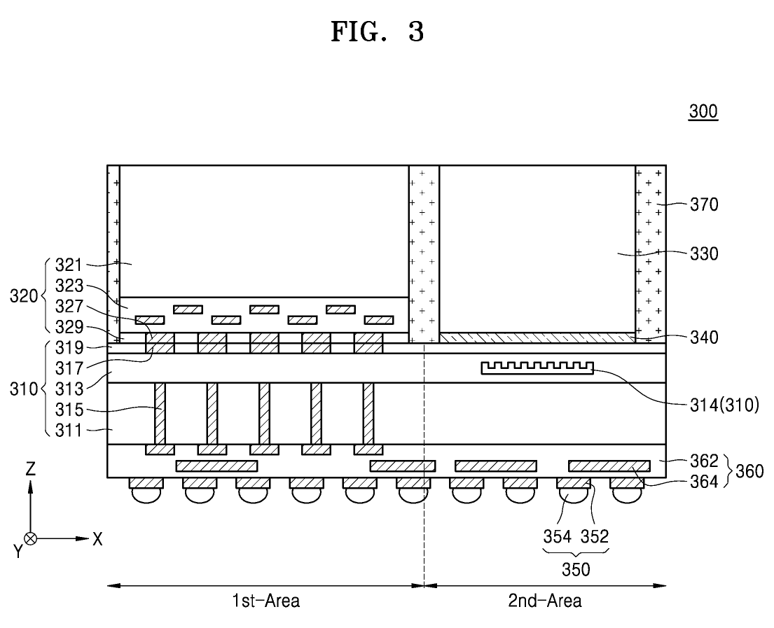

The first connection terminals 250 may be disposed on pads on the bottom surface of the interposer 200 and may be electrically connected to the through electrodes 220. In addition, the first connection terminals 250 may be connected to pads on the top surface of the interposer 200 through the through electrodes 220. As described above, the interposer 200 may be mounted on the package substrate 100 through the first connection terminals 250. The first connection terminals 250 may include, for example, a pillar and a solder, or may include only a solder. With reference to the first connection terminals 250, second connection terminals 350 in the OEU package 300 of FIG. 3 are described in more detail.

In the semiconductor package 1000 of an embodiment, the interposer 200 may be used for transmitting electrical signals between the OEU packages 300, the first semiconductor device 400, and the second semiconductor devices 500 or may be used for transmitting power or ground from the package substrate 100 to the OEU packages 300, the first semiconductor devices 400, and the second semiconductor devices 500. Accordingly, the interposer 200 may not include elements, such as an active element or a passive element. On the other hand, in some embodiments, an underfill may fill the gap between the interposer 200 and the package substrate 100 and between the first connection terminals 250. On the other hand, when a molded underfill (MUF) process is performed on the package substrate 100, the underfill may be omitted.

As shown in FIG. 1, the first semiconductor device 400 may be arranged on the central portion of the top surface of the interposer 200 in the X direction. The second semiconductor devices 500 may be away from the first semiconductor 400 in the X direction on both sides of the first semiconductor device 400. The OEU packages 300 may be spaced apart from the first semiconductor device 400 in the Y direction. However, the arrangement structure of the first semiconductor device 400, the second semiconductor devices 500, and the OEU packages 300 is not limited to the arrangement structure of FIG. 1.

In FIG. 1, the semiconductor package 1000 is shown to include one first semiconductor device 400, four second semiconductor devices 500, and four OEU packages 300, but the number of first semiconductor devices 400, the number of second semiconductor devices 500, and the number of OEU packages 300 included in the semiconductor package 1000 are not limited thereto. In some embodiments, the semiconductor package 1000 may include only one of the second semiconductor devices 500 and the first semiconductor device 400.

The OEU packages 300 may be mounted on the interposer 200 by the second connection terminals 350. An underfill 380 may be placed between the OEU packages 300 and the interposer 200. In some embodiments, the underfill 380 may be replaced with an adhesive layer. In addition, when the sealant 600 is formed in the MUF process, the underfill 380 may be omitted.

The OEU package 300 may include a photonic integrated circuit (PIC) chip (e.g., the PIC chip 310 in FIG. 3), an electronic integrated circuit (EIC) chip (e.g., the EIC chip 320 in FIG. 3) an optical path block (e.g., the optical path block 330 in FIG. 3), an RDL (e.g., the RDL 360 in FIG. 3), and an internal sealant (e.g., the internal sealant 370 in FIG. 3). The EIC chip 320 may be disposed on the left side of the PIC chip 310 in the X direction. The optical path block 330 may be disposed on the right side of the PIC chip 310 in the X direction. However, in some embodiments, the positions of the optical path block 330 and the EIC chip 320 may be interchanged. The specific structure of the OEU package 300 is described in more detail with reference to FIG. 3.

The first semiconductor device 400 may include a logic chip. Accordingly, the first semiconductor device 400 may include multiple logic elements therein. The logic elements may include, for example, an AND, a NAND, an OR, a NOR, an exclusive OR (XOR), an exclusive NOR (XNOR), an inverter (INV), an adder (ADD), a delay (DLY), a filter (FIL), and a multiplexer (MXT/MXIT), an OR/AND/INVERTER (OAI), an AND/OR (AO), an AND/OR/INVERTER (AOI), a D flip-flop, a reset flip-flop, a master-slave flip-flop, a latch, a counter, or buffer elements. The logic elements may perform various signal processing tasks, such as analog signal processing, analog-to-digital (A/D) conversion, and control. The first semiconductor device 400 may be referred to as, depending on a function thereof, a central processing unit (CPU) chip, a microprocessor unit (MPU) chip, a graphics processing unit (GPU) chip, a neural processing unit (NPU) chip, a tensor processing unit (TPU) chip, a system-on-glass (SOG) chip, an application-specific integrated circuit (ASIC) chip, an application processor (AP) chip, or a control chip.

The first semiconductor device 400 having a chip structure may have a system-on-chip (SOC) structure or a chiplet structure. For example, in the semiconductor package 1000 of an embodiment, the first semiconductor device 400 may have an SOC structure. However, the structure of the first semiconductor device 400 is not limited to the SOC structure. For reference, the chiplet structure is a configuration opposite to the SOC structure. The chiplet structure may have a structure in which a logic chip is divided into separate chips for each function and the chips are connected to each other. For example, in the chiplet structure, logic chips, such as a CPU chip, a GPU chip, an input/output (I/O) chip, a communication modem chip, and other functional chips, may be individually formed and connected to each other. The chiplet structure may overcome the performance limitations of a single chip of the SOC structure.

In the semiconductor package 1000 of an embodiment, the first semiconductor device 400 may include elements that support communication. However, in some embodiments, the elements that support communication may be separately provided as another chip (e.g., a modem chip) or may be coupled to the first semiconductor device 400 on the interposer 200.

The first semiconductor device 400 may include a substrate and a multi-wiring layer. An integrated circuit layer may be formed on the active surface of the substrate. The integrated circuit layer may include multiple logic elements. The multi-wiring layer may be disposed on the bottom surface of the substrate and may include multilayered wires. The bottom surface of the first semiconductor device 400 may include a front surface that is an active surface, and the top surface of the first semiconductor device 400 may include a back surface that is an inactive surface. In other words, the bottom surface of the multi-wiring layer may correspond to the front surface of the first semiconductor device 400 and the top surface of the substrate may correspond to the back surface of the first semiconducting device 400.

The first semiconductor device 400 may be mounted on the interposer 200 by third connection terminals 450. The size of the third connection terminal 450 may be less than the size of the first connection terminal 250. However, the structure and the material of the third connection terminal 450 may be the same as the structure and the material of the first connection terminal 250. In addition, an underfill 430 may be arranged between the first semiconductor device 400 and the interposer 200. The underfill 430 may fill the gap between the first semiconductor device 400 and the interposer 200 and cover the third connection terminals 450. On the other hand, when the sealant 600 is formed by the MUF process, the underfill 430 may be omitted. In some embodiments, an adhesive layer may be arranged instead of the underfill 430.

The second semiconductor device 500 may include, for example, a volatile memory device, such as dynamic random-access memory (DRAM) and static random-access memory (SRAM), or a non-volatile memory device, such as flash memory. The second semiconductor device 500 may include a single chip or may include a package including multiple chips. For example, when the second semiconductor device 500 is a single chip, the second semiconductor device 500 may include one memory chip. When the second semiconductor device 500 is a package, the second semiconductor device 500 may include multiple memory chips. In the semiconductor package 1000 of an embodiment, the memory chip of the second semiconductor device 500 may include, for example, a DRAM chip. However, the type of the memory chip of the second semiconductor device 500 is not limited to the DRAM chip.

In the semiconductor package 1000 of an embodiment, the second semiconductor device 500 may include a high bandwidth memory (HBM) package as a memory package. As a brief description of the HBM package structure, the second semiconductor device 500 may include a base chip, multiple core chips stacked on the base chip, and an internal sealant. In addition, the base chip and the core chips may include at least one through electrode therein. On the other hand, the uppermost core chip of the core chips may not include a through electrode.

The base chip may include logic elements. Thus, the base chip may be a logic chip. This base chip may be arranged below the core chips, may integrate and transmit signals of the core chips to the outside, and may also transmit signals and a power source from the outside to the core chips. Thus, the base chip may be referred to as a buffer chip or a control chip. In addition, each of the core chips may include a memory chip. For example, each of the core chips may include a DRAM chip. The core chip may be stacked on the base chip or the lower core chip through hybrid copper bonding (HCB), bonding using a connection terminal, or bonding using an anisotropic conductive film (ACF). The HCB may refer to a combination of pad-to-pad bonding and insulator-to-insulator bonding.

The core chips on the base chip may be sealed by the internal sealant. However, the top surface of the uppermost core chip among the core chips may not be covered by the internal sealant. In some embodiments, a top dummy chip may be disposed on the uppermost core chip. The top dummy chip may be arranged to meet the joint electron device engineering council (JEDEC) specification of the HBM package.

In the semiconductor package 1000 of an embodiment, the second semiconductor devices 500 are not limited to the HBM package. For example, the second semiconductor device 500 may have a general package structure as a memory package. For example, the second semiconductor device 500 may include an upper package substrate and a plurality of memory chips stacked on the upper package substrate. In addition, the memory chips may be stacked on the upper package substrate via a bonding wire or may be stacked on the upper package substrate by at least one bump and at least one TSV.

The second semiconductor devices 500 may be mounted on the interposer 200 via fourth connection terminals 550. The size of the fourth connection terminal 550 may be less than the size of the first connection terminal 250, and the structure and the material of the fourth connection terminal 550 may be the same as the structure and the material of the first connection terminal 250. In addition, an underfill 530 may be arranged between the second semiconductor device 500 and the interposer 200. The underfill 530 may fill the gap between the second semiconductor device 500 and the interposer 200 and may cover the fourth connection terminals 550. On the other hand, when the sealant 600 is formed by the MUF process, the underfill 530 may be omitted. In some embodiments, an adhesive layer may be arranged instead of the underfill 530.

The sealant 600 may at least partially surround (e.g., seal) the OEU package 300, the first semiconductor device 400, and the second semiconductor device 500 on the interposer 200. Specifically, the sealant 600 may cover the side surfaces of the OEU package 300, the first semiconductor device 400, and the second semiconductor device 500, and may fill the gap between the OEU package 300 and the first semiconductor device 400 and between the first semiconductor device 400 and the second semiconductor device 500. On the other hand, when the underfill 380, 430, or 530 is arranged between the interposer 200 and the OEU package 300, the first semiconductor device 400, or the second semiconductor device 500, the sealant 600 may cover the side surfaces of the underfill 380, 430, or 530.

In addition, as shown in FIGS. 2A and 2B, the top surface of each of the OEU package 300, the first semiconductor device 400, and the second semiconductor device 500 may be exposed from the sealant 600. However, in some embodiments, except for the OEU packages 300, the top surface of at least one from among the first semiconductor device 400 and the second semiconductor device 500 may be covered by the sealant 600.

The sealant 600 may include an insulating material such as, for example, a thermosetting resin (e.g., an epoxy resin), a thermoplastic resin (e.g., polyimide), or a resin including a reinforcing material (e.g., an inorganic filler). For example, the sealant 600 may include ABF, FR-4, BT resin, and the like. In addition, the sealant 600 may include a molding material (e.g., epoxy molding compound (EMC)) or a photosensitive material (e.g., photo-imageable encapsulant (PIE)). However, the material of the sealant 600 is not limited to the above-described materials.

In the semiconductor package 1000 of an embodiment, the optical path block 330 of the OEU package 300 may be attached to the PIC chip 310 through an adhesive film 340 having a ring shape. Thus, the optical path block 330 may be attached onto the PIC chip 310 with a uniform height and may also be precisely aligned with an optical coupler 314 in the PIC chip 310. As a result, the reliability of the PIC chip 310 and the OEU package 300 including the PIC chip 310 may be improved. In addition, the reliability of the entire semiconductor package 1000 may also be improved.

For reference, in a comparative embodiment, when an optical path block is attached onto a PIC chip with a transparent adhesive layer, such as glue, voids, such as bubbles, may be generated in the transparent adhesive layer, thereby increasing optical loss, such as insertion loss. In addition, in the comparative embodiment, as pressure is applied to the optical path block and the adhesive layer has fluidity in the process of attaching the optical path block onto the PIC chip, the optical path block may be tilted to one side, thereby causing misalignment with the optical coupler. Furthermore, in the comparative embodiment, the adhesive layer with fluidity may overflow to cover the optical path block or the adhesive layer with fluidity may bleed into the underfill or connection terminals of adjacent semiconductor elements, thereby causing delamination of the semiconductor elements. However, in the OEU package 300 of the semiconductor package 1000 of an embodiment of the present disclosure, the optical path block 330 may be attached onto the PIC chip 310 through an adhesive film having a ring shape, thereby solving all of the above-described problems.

FIG. 3 is an enlarged cross-sectional view of the OEU package in the semiconductor package of FIG. 2B. Descriptions that are substantially the same as those given with reference to FIGS. 1-2B may be briefly given or omitted.

Referring to FIG. 3, in the semiconductor package 1000 of an embodiment, the OEU package 300 may include the PIC chip 310, the EIC chip 320, the optical path block 330, the RDL 360, and the internal sealant 370.

The PIC chip 310 may be disposed on the RDL 360. The PIC chip 310 is an integrated circuit chip that uses light, and may provide large-capacity information transmission, high-speed signal processing, transmission loss minimization, energy consumption minimization, and the like. The PIC chip 310 may include optical elements, such as a light source, an optical waveguide, a passive circuit, and an optical-to-current converter therein. The passive circuit may refer to a device for changing the characteristics of light and may include a filter, a duplexer, an optical coupler, an interferometer, a spectrometer, and the like.

The PIC chip 310 may include a substrate 311, an active layer 313, the optical coupler 314, through electrodes 315, pads 317, and a protective layer 319. The substrate 311 may include Si. However, the material of the substrate 311 is not limited to Si. The active layer 313 may be disposed on the substrate 311 and may include the various optical elements described above. In FIG. 3, only one optical coupler 314 is shown for convenience of explanation. A light source, an optical waveguide, a passive circuit, and an optical-to-current converter may also be provided. The optical coupler 314 may include, for example, a Bragg grating. However, the optical coupler 314 is not limited to the Bragg grating.

The through electrodes 315 may extend through the substrate 311. Since the substrate 311 includes Si, the through electrodes 315 may include a TSV. The through electrodes 315 may be connected to redistribution lines 364 of the RDL 360 and may be connected to the wiring of the active layer 313. The through electrodes 315 may be connected to the pads 317 through the wiring of the active layer 313. In some embodiments, the through electrodes 315 may penetrate the substrate 311 and the active layer 313, and the through electrodes 315 may be directly connected to the pads 317.

The pads 317 may be disposed on the top surface of the active layer 313. The pads 317 may be connected to the wiring of the active layer 313 and may be connected to the electrodes 315 through the wiring of the active layer 313. In some embodiments, the pads 317 may be directly connected to the through electrodes 315. The pads 317 may include, for example, at least one from among Al, Cu, nickel (Ni), tungsten (W), platinum (Pt), and gold (Au). In the PIC chip 310 of an embodiment, the pads 317 may include Cu. However, the material of the pads 317 is not limited to Cu.

The protective layer 319 may cover and protect the top surface of the active layer 313. The protective layer 319 may include an insulating film. The protective layer 319 may include, for example, an oxide film, a nitride film, a carbide film, a polymer, or a combination thereof. However, the material of the protective layer 319 is not limited thereto. The protective layer 319 may have a single-film or multi-film structure. The pads 317 may be connected to the wiring of the active layer 313 through the protective layer 319.

On the other hand, the PIC chip 310 may be divided into a first area and a second area in the X direction. The first area may correspond to an area in which the EIC chip 320 is arranged, and the second area may correspond to an area in which the optical path block 330 is arranged. As shown in FIG. 3, the through electrodes 315 may pass through the substrate 311 in the first area. In addition, in the second area, the optical coupler 314 may be arranged within the active layer 313 and optically aligned with the optical path block 330.

The EIC chip 320 may be mounted on the PIC chip 310. The EIC chip 320 may include a substrate 321, an active layer 323, pads 327, and a protective layer 329. The substrate 321 may include Si. However, the material of the substrate 321 is not limited to Si. The active layer 323 may be arranged below the substrate 321 and may include various electronic elements that support the operation of the PIC chip 310. For example, the active layer 323 may include a trans-impedance amplifier (TIA), a clock and data recovery (CDR), and one or more drivers.

In some embodiments, the TIA may be implemented, as a kind of current-to-voltage converter, with at least one operational amplifier. The TIA may amplify the current output of the photodetector or other type of sensor of the PIC chip 310 to a usable voltage. The TIA may provide low impedance to a photodiode in the PIC chip 310.

In some embodiments, the CDR may extract timing and data information from a serial data stream in serial communication of digital data. In some embodiments, some high-speed serial data streams may be transmitted without an accompanying clock signal. The CDR may generate a clock from an appropriate frequency reference and then phase-shift the clock to match the transitions of the data stream. In some embodiments, a driver may be used to drive various functions of the PIC chip 310.

The pads 327 may be disposed on the bottom surface of the active layer 323. The pads 327 may be connected to wires in the active layer 323. The material of the pads 327 is the same as the material of the pads 317 of the PIC chip 310.

The protective layer 329 may cover and protect the bottom surface of the active layer 323. The material and structure of the protective layer 329 may be the same as the material and the structure of the protective layer 319 of the PIC chip 310. The pads 327 may be connected to the wires in the active layer 323 through the protective layer 329.

The EIC chip 320 may be mounted on the PIC chip 310 through the HCB. Specifically, the pads 317 of the PIC chip 310 may be bonded to the pads 327 of the EIC chip 320, and the protective layer 319 of the PIC chip 310 may be bonded to the protective layer 329 of the EIC chip 320. In some embodiments, the EIC chip 320 may be mounted on the PIC chip 310 through at least one fine connection terminal. The at least one fine connection terminal may be arranged between the pads 317 of the PIC chip 310 and the pads 327 of the EIC chip 320.

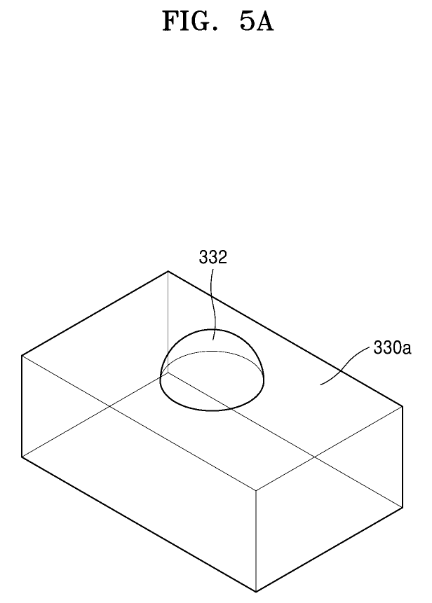

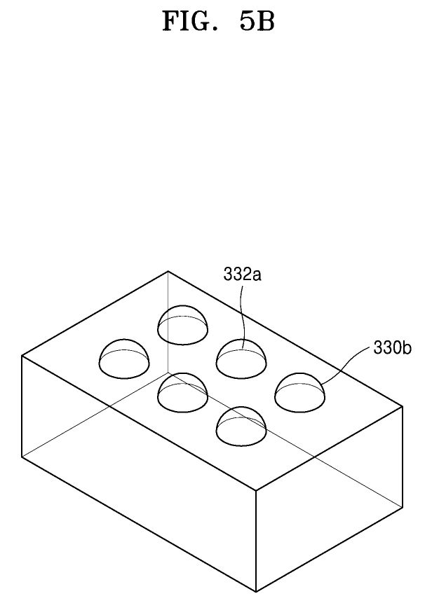

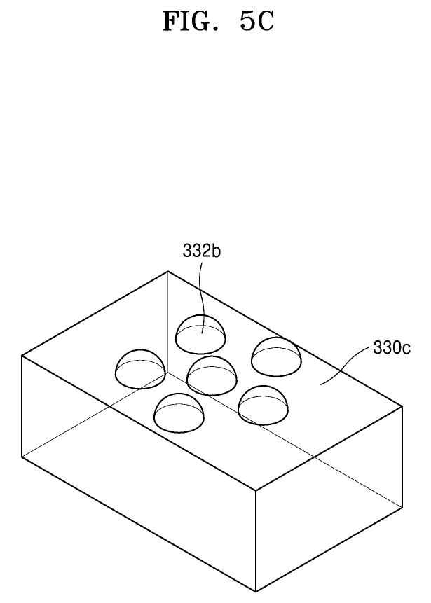

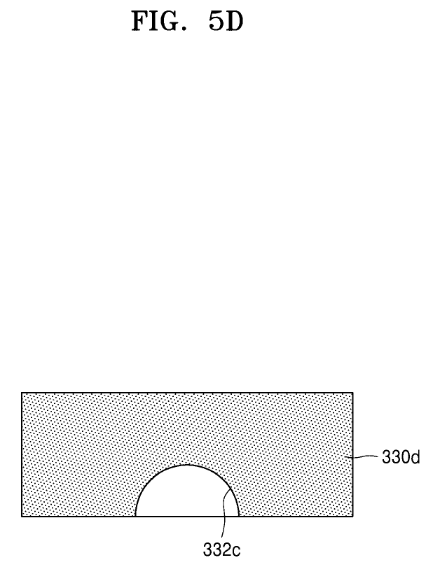

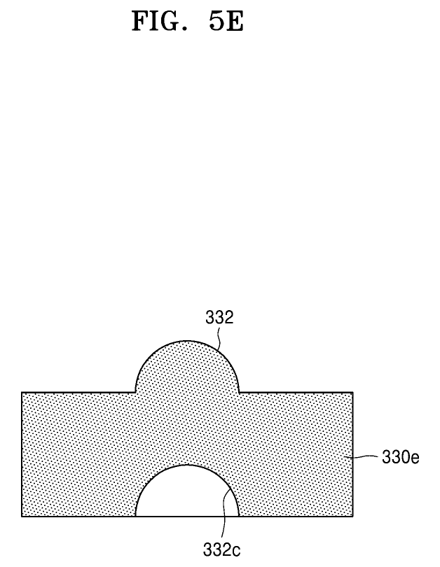

The optical path block 330 may be arranged at a position corresponding to the optical coupler 314 of the second area of the PIC chip 310. More specifically, the optical path block 330 may be disposed above the optical coupler 314. In addition, the optical path block 330 may be arranged at a position where light can be optimally transmitted to the optical coupler 314 through a microlens (e.g., the convex microlens 332 in FIG. 5A) of the optical path block 330. The optical path block 330 may include a transparent material through which light can be transmitted. For example, the optical path block 330 may include Si, SiO₂, glass, transparent polymer, and the like. However, the material of the optical path block 330 is not limited to the above-described materials.

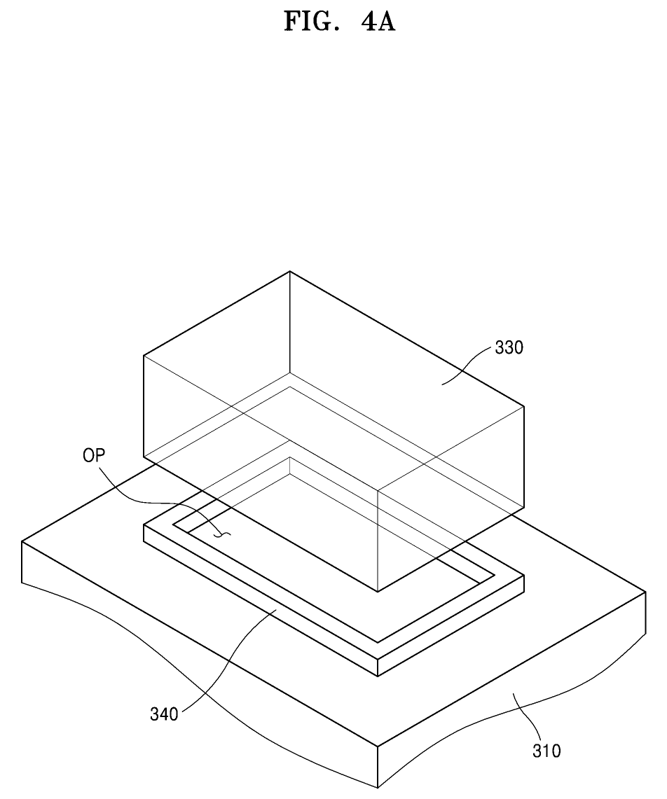

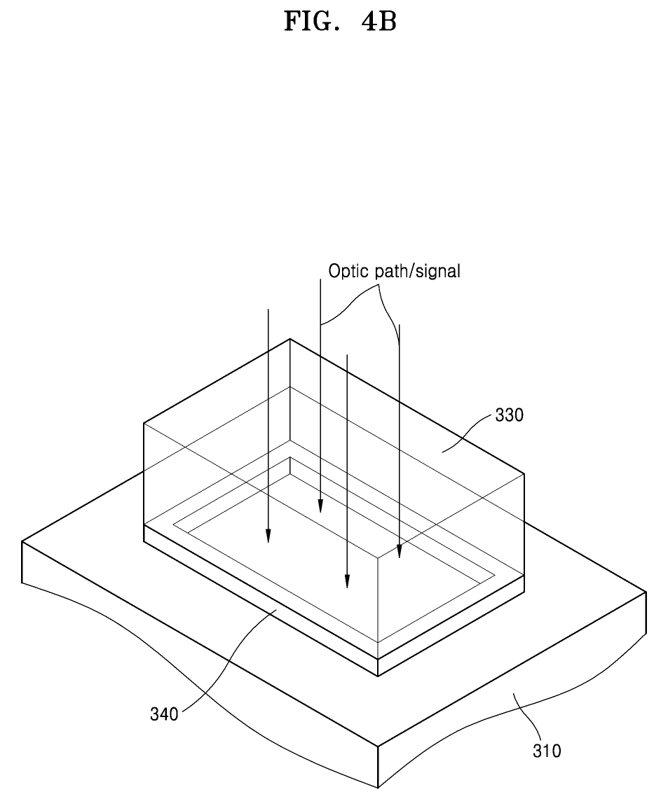

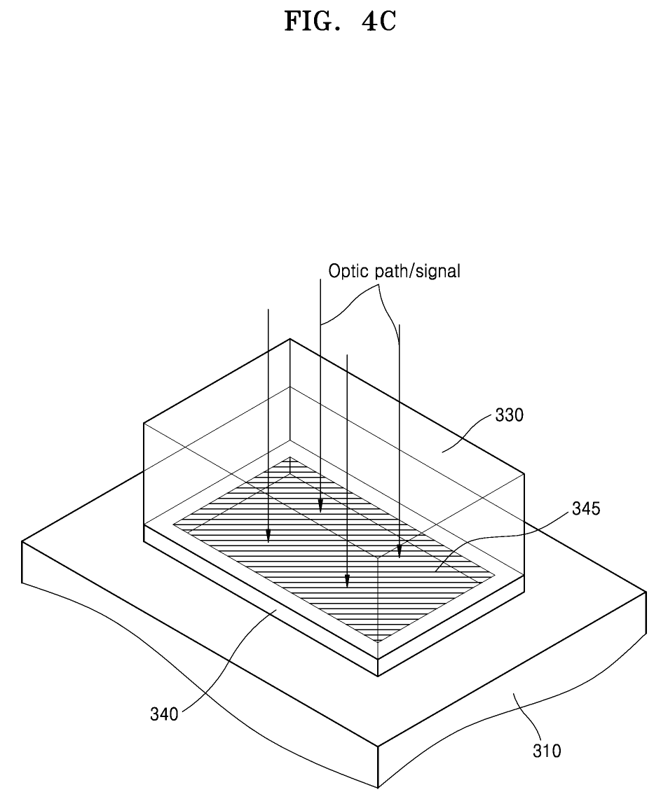

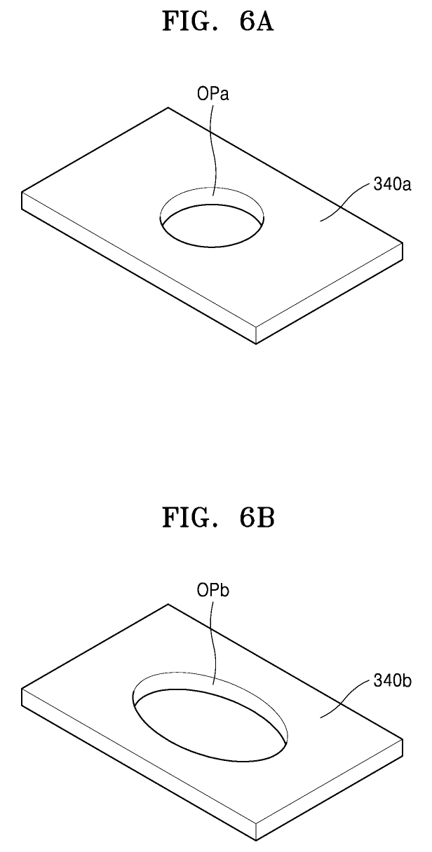

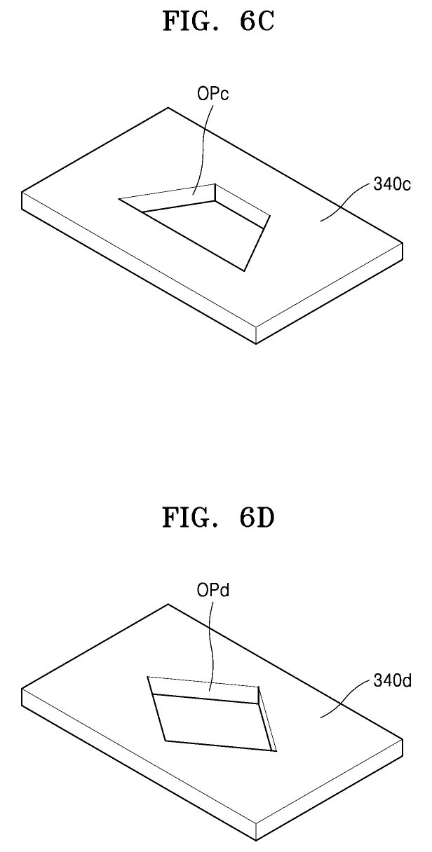

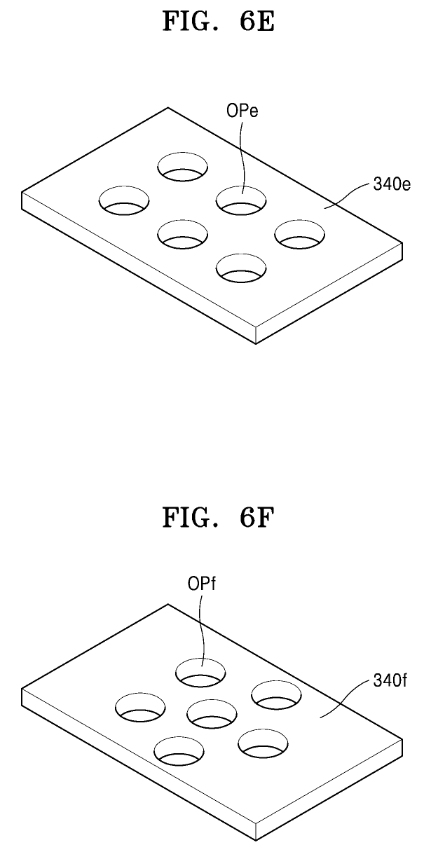

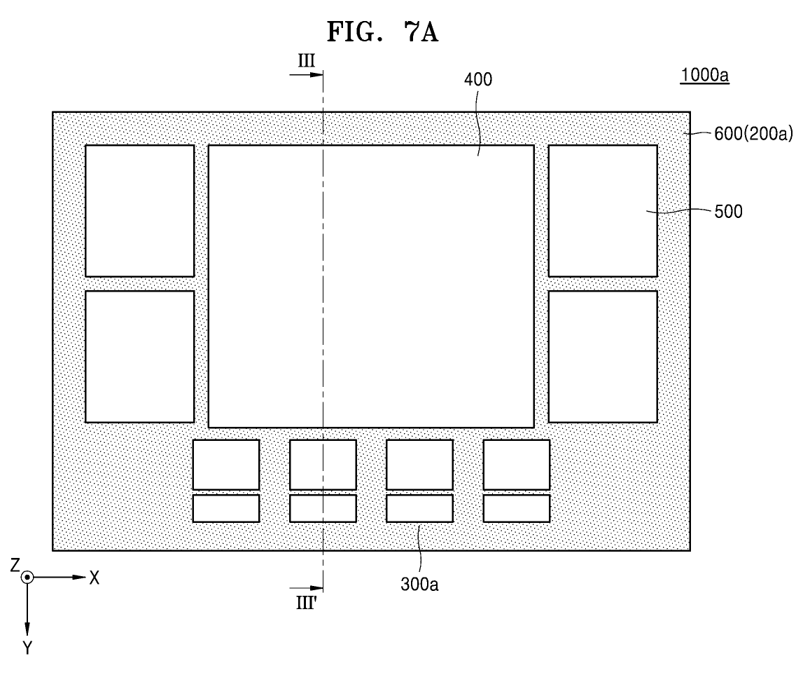

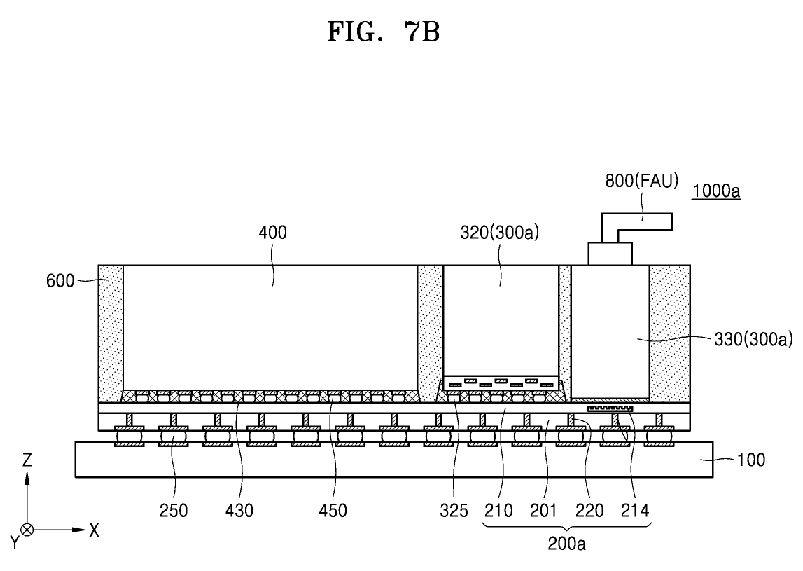

The optical path block 330 may be attached to the PIC chip 310 through the adhesive film 340 having a ring shape. An opening (see opening OP in FIG. 4A) through which light can pass may be formed in the center portion of the adhesive film 340. The light transmitted through the optical path block 330 may pass through the opening OP of the adhesive film 340 and may be incident on the optical coupler 314 of the PIC chip 310. The specific structure and various forms of the adhesive film 340 are described in more detail with reference to FIGS. 4A-4C and 6A-6F.

The optical path block 330 may include microlenses formed on at least one from among a top surface and a bottom surface of the optical path block 330. The microlenses may be formed in a two-dimensional array structure. The arrangement structure and the number of microlenses are described in more detail with reference to FIGS. 5A-5E.

On the other hand, as shown in FIG. 2B, the optical path block 330 may be coupled to a fiber assembly unit (FAU) 800. When the microlenses are not formed in the optical path block 330, the microlenses may be placed inside the FAU 800.

The RDL 360 may be arranged below the PIC chip 310 and may rewire a lower pad of the PIC chip 310 to an outer region of the PIC chip 310. Therefore, the RDL 360 may be, for example, a fan-out RDL. For reference, the lower pad of the PIC chip 310 may be arranged in the first area and connected to the through electrodes 315. In some embodiments, the RDL 360 may have a greater area than an area of the PIC chip 310 and may be arranged below the PIC chip 310. In some embodiments, the RDL 360 may be omitted.

The RDL 360 may include a body insulating layer 362 and the redistribution lines 364. The body insulating layer 362 may be formed of an insulating material such as, for example, a PID resin, and may further include an inorganic filler. However, the material of the body insulating layer 362 is not limited to the above-described material. The body insulating layer 362 may have a multilayer structure according to the multilayer structure of the redistribution lines 364. However, in FIG. 3, for convenience of explanation, the body insulating layer 362 is shown as a single layer structure. The redistribution lines 364 may be formed of multiple layers, and the redistribution lines 364 of different layers may be connected to each other by vias.

The second connection terminals 350 may be disposed on the bottom surface of the body insulating layer 362. The second connection terminals 350 may be disposed on pads on the bottom surface of the body insulating layer 362. The second connection terminals 350 may be electrically connected to the redistribution lines 364 of the RDL 360. The second connection terminal 350 may include a pillar 352 and a solder 354. In some embodiments, the second connection terminal 350 include only the solder 354, and the pillar 352 may be omitted.

The pillar 352 may include Cu and may function as a pad. When the pillar 352 functions as a pad, the pad may not be formed on the bottom surface of the RDL 360. The solder 354 may be disposed on the pillar 352. The solder 354 may include, for example, Sn, indium (In), bismuth (Bi), antimony (Sb), Cu, Ag, zinc (Zn), and/or alloys thereof. In some embodiments, the solder 354 may be referred to as a bump, a solder bump, or the like.

The internal sealant 370 may at least partially surround (e.g., seal) the EIC chip 320 and the optical path block 330 on the PIC chip 310. Specifically, the internal sealant 370 may cover side surfaces of the EIC chip 320 and the optical path block 330 and may fill the gap between the EIC chip 320 and the optical path block 330. As shown in FIG. 3, the internal sealant 370 may not cover the top surfaces of the EIC chip 320 and the optical path block 330. In some embodiments, the internal sealant 370 may cover the top surface of EIC chip 320.

The internal sealant 370 may include, for example, a thermosetting resin (e.g., an epoxy resin), a thermoplastic resin (e.g., polyimide), or a resin including an inorganic filler (e.g., ABF, FR-4, BT, and the like). In addition, the internal sealant 370 may include a molding material (e.g., EMC) or a photosensitive material (e.g., PIE). In some embodiments, the internal sealant 370 may include SiO₂, SiCN, SiON, SiN, or a polymer, and may be formed by a chemical vapor deposition (CVD) method or a spin coating method.

On the other hand, when the RDL 360 is wider than the PIC chip 310, the internal sealant 370 may cover the side surfaces and an outer portion of the top surface of the PIC chip 310, and the side surfaces of the EIC chip 320 and the optical path block 330 on the RDL 360.

In addition, in the semiconductor package 1000 of some embodiments, the OEU package 300 may further include a transparent support layer disposed on the EIC chip 320, the optical path block 330, and the internal sealant 370. This transparent support layer may support the main components of the OEU package 300 (e.g., the EIC chip 320, the optical path block 330, and the internal sealant 370). In addition, the transparent support layer may support optical communication of the PIC chip 310. Thus, the transparent support layer may be formed of a material through which light can be transmitted. For example, the transparent support layer may include Si. However, the material of the transparent support layer is not limited to Si. For example, the transparent support layer may include SiO₂, glass, or a transparent polymer, which can be used for the optical path block 330, and may also include a transparent material other than the above-described materials. When the transparent support layer is provided, the microlenses may be formed in the transparent support layer, and the transparent support layer may be connected to the FAU 800. The light for communication may be received and integrated through the microlenses of the transparent support layer and may be transmitted to the optical coupler 314 of the PIC chip 310 through the optical path block 330.

FIGS. 4A-4C are perspective views of a structure in which the optical path block is coupled to the PIC chip, in the OEU package of FIG. 3, wherein FIG. 4A shows a structure before the optical path block is attached to the PIC chip, and FIGS. 4B and 4C show a structure in which the optical path block is attached to the PIC chip. Descriptions that are substantially the same as those given with reference to FIGS. 1-3 may be briefly given or omitted.

Referring to FIGS. 4A and 4B, in the OEU package 300 of the semiconductor package 1000 of an embodiment, the optical path block 330 may be attached onto the PIC chip 310 through the adhesive film 340 have a ring shape. For example, the adhesive film 340 may have a rectangular ring shape or a rectangular frame shape and may include an opening OP in a central portion thereof. The opening OP may refer to a space in which a tangible material such as a liquid or a solid is not present. The horizontal cross-section of the opening OP may have a rectangular shape corresponding to, for example, a rectangular ring shape of the adhesive film 340. However, the horizontal cross-section of the opening OP is not limited to a rectangular shape. For example, the adhesive film 340 may have various shapes as long as light can pass therethrough. Various forms of the opening OP are described in more detail with reference to FIGS. 6A-6F.

The adhesive film 340 may have a size that can cover the outer portion of the bottom surface of the optical path block 330. For example, as shown in FIG. 4B, the outer side surface of the adhesive film 340 may be substantially coplanar with the side surface of the optical path block 330. However, in some embodiments, the outer side surface of the adhesive film 340 may not match the side surface of the optical path block 330. For example, the outer side surface of the adhesive film 340 may protrude outward or may be recessed inward from the side surface of the optical path block 330.

The adhesive film 340 may include an absorbent material or a reflective material. The absorbent material or the reflective material of the adhesive film 340 may remove noise by reflecting or absorbing light corresponding to noise incident on the outer portion thereof. The absorbent material may include, for example, Si, organic material, and the like. The absorption rate of the absorbent material may be increased by adding sulfur (S) or molybdenum (Mo) through atomic-level micro-deposition. The reflective material may generally include a metallic material. However, the reflective material is not limited to a metallic material.

In the OEU package 300 of the semiconductor package 1000 of an embodiment, the adhesive film 340 may include a die attach film (DAF). For example, the adhesive film 340 having a ring shape may be produced by cutting the inside of the DAF with a cutter to form an opening. The DAF is an adhesive film which may be used for attaching a chip. When attaching the optical path block 330, the thickness uniformity of the DAF may be maintained by maintaining only the outer portion thereof in a ring shape.

For reference, an adhesive layer, such as glue, is liquid, thereby causing quality defects, such as height imbalance and voids. In addition, to produce the adhesive layer in the form of a film, it may take a long time to evaluate the cost and ensure reliability of material components. On the other hand, when the DAF is used for attaching the optical path block 330 in the form of a sheet without the opening OP, the control of performance and material for transmittance is required and there are still issues of cost and time. However, since the adhesive film 340 of an embodiment has a ring shape including the opening OP, there may be no need to consider the transmittance. In addition, by using the DAF in which reliability has already been verified in a ring shape including an opening, height and alignment may be precisely controlled without affecting optical loss. Specifically, by using materials having a record of existing mass production, the thickness may be precisely controlled in the form of a film, and thus the height of the optical path block 330 may be precisely controlled when attaching the optical path block 330. In addition, by forming the opening in a region on the optical path, the insertion loss may be significantly improved. Furthermore, when the microlens is formed on the bottom surface of the optical path block 330, the opening may be disposed on the bottom surface of the microlens, thereby improving the optical path and the insertion loss. In a comparative embodiment, when the microlens is formed on the bottom surface of an optical path block and the optical path block is attached onto a PIC chip through the adhesive layer, the adhesive layer may not completely fill the inside of the microlens uniformly. Thus, in the comparative embodiment, the optical path may deteriorate and the insertion loss may increase.

Referring to FIG. 4C, in the OEU package 300 of the semiconductor package 1000 of an embodiment, the opening OP of the adhesive film 340 may be filled with a gap-fill layer 345. The gap-fill layer 345 may include a transparent material. For example, the gap-fill layer 345 may include a transparent material, such as SiO₂, polymeric thermal interface materials (TIM), thermal grease, and optical glue. In the OEU package 300 of the semiconductor package 1000 of an embodiment, the adhesive film 340 in a ring shape may function as a guide even when the gap-fill layer 345 is included, thereby preventing the overflow and bleeding that occur when only glue is used.

FIGS. 5A-5E are perspective views and cross-sectional views of various structures of the optical path block, in the OEU package of FIG. 3. Descriptions that are substantially the same as those given with reference to FIGS. 1-4B may be briefly given or omitted.

Referring to FIG. 5A, in the OEU package 300 of the semiconductor package 1000 of an embodiment, an optical path block 330a may include a convex microlens 332 formed on a central portion of a top surface thereof. The convex microlens 332 may protrude outward from the top surface of the optical path block 330a.

The microlens 332 may collect and cause the incident light to enter the optical coupler 314 of the PIC chip 310. The height of the optical path block 330a (i.e., the optical height of the optical path block 330a) may be kept uniform in order for light to concentrate through the microlens 332 and be optimally incident on the optical coupler 314. For example, in a comparative embodiment, when an optical path block is tilted, light may not be accurately collected through the microlens, thereby deteriorating the collection efficiency to an optical coupler. In the OEU package 300 of the semiconductor package 1000 of an embodiment, when the optical path block 330a is attached onto the PIC chip 310, the optical height of the optical path block 330a may be uniformly controlled through the adhesive film 340 having a ring shape, thereby solving above-described problem. On the other hand, microlenses 332a may be formed through a nano-imprint process. For example, the optical path block 330a including the microlenses 332a may be formed by fabricating a mold in which a pattern corresponding to the microlenses 332a is engraved and then pressing the mold on a substrate having a material such as glass to transfer the shape of the microlenses 332a. That is, the main body portion may be integrally formed with the microlenses 332a to form the optical path block 330a.

Referring to FIG. 5B, in the OEU package 300 of the semiconductor package 1000 of an embodiment, an optical path block 330b may include the microlenses 332a arranged in a two-dimensional array structure on a top surface of the optical path block 330b. Each of the microlenses 332a may collect the incident light into the optical coupler 314 of the PIC chip 310. In addition, each of the microlenses 332a may be arranged at a location corresponding to the micro optical fibers of the FAU 800. In FIG. 5B, the microlenses 332a are arranged in a 2 by 3 array structure, but are not limited thereto. The microlenses 332a may be arranged on the top surface of the optical path block 330b in various array structures.

Referring to FIG. 5C, in the OEU package 300 of the semiconductor package 1000 of an embodiment, the optical path block 330c may include microlenses 332b disposed concentrically on a top surface of the optical path block 330c . For example, the microlenses 332b may include a central microlens and outer microlenses surrounding the central microlens in a circular or pentagonal shape. Each of the microlenses 332b may collect the incident light into the optical coupler 314 of the PIC chip 310. In addition, each of the microlenses 332b may be arranged at a location corresponding to the micro optical fiber of the FAU 800. In FIG. 5C, one central microlens in the center and five outer microlenses surrounding the same are shown, but the microlenses 332b may be arranged in various numbers on the top surface of the optical path block 330c in a circular, elliptical, or polygonal structure.

Referring to FIG. 5D, in the OEU package 300 of the semiconductor package 1000 of an embodiment, an optical path block 330d may include a concave microlens 332c formed in a central portion of a bottom surface of the optical path block 330d. The concave microlens 332c may collect the incident light into the optical coupler 314 of the PIC chip 310. The concave microlens 332c may be recessed inward from the bottom surface of the optical path block 330d. In FIG. 5D, a structure in which one concave microlens 332c is arranged is shown, but the structure is not limited thereto. Similar to the convex microlenses in FIGS. 5B and 5C, the concave microlens 332c may be disposed at (e.g., in) the bottom surface of the optical path block 330d in various forms such as an array structure or a concentric circle.

Referring to FIG. 5E, in the OEU package 300 of the semiconductor package 1000 of an embodiment, an optical path block 330e may include the convex microlens 332 formed on a central portion of the top surface of the optical path block 330e, and the concave microlens 332c formed in a central portion of the bottom surface of the optical path block 330e. The convex microlenses 332 and the concave microlens 332c may collect the incident light into the optical coupler 314 of the PIC chip 310. The convex microlens 332 may correspond to the convex microlens 332 of FIG. 5A, and the concave microlens 332c may correspond to the concave microlens 332c of FIG. 5D. In FIG. 5E, a structure in which one convex microlens 332 is disposed at (e.g., on) the top surface and one concave microlens 332c is disposed at (e.g., in) the bottom surface of the optical path block 330e is shown, but the structure is not limited thereto. Similar to the convex microlenses in FIGS. 5B and 5C, the convex microlens 332 and the concave microlenses 332c may be disposed at (e.g., in or on) the top and bottom surfaces of the optical path block 330e in various forms, such as an array structure or a concentric circle.

FIGS. 6A-6F are perspective views of various structures of an adhesive film in the OEU package of FIG. 3. Descriptions that are substantially the same as those given with reference to FIGS. 1-5E may be briefly given or omitted.

Referring to FIG. 6A, in the OEU package 300 of the semiconductor package 1000 of an embodiment, an adhesive film 340a may include a circular opening OPa formed in a central portion of the adhesive film 340a. The adhesive film 340a still may have a ring shape due to the presence of the circular opening OPa. However, in the adhesive film 340a, since the film portion occupies a wider area than the circular opening OPa portion, the adhesive film 340a may be in the form of a sheet including the circular opening OPa. The adhesive film 340a may correspond to the optical path block 330a of FIG. 5A above. Specifically, light collected through the convex microlens 332 of the optical path block 330a of FIG. 5A may pass through the circular opening OPa of the adhesive film 340a and may be incident on the optical coupler 314 of the PIC chip 310.

Referring to FIG. 6B, in the OEU package 300 of the semiconductor package 1000 of an embodiment, an adhesive film 340b may include an elliptical opening OPb formed in a central portion of the adhesive film 340b. The adhesive film 340b may still have a ring shape due to the presence of the elliptical opening OPb. However, in the adhesive film 340b, since the film portion occupies a wider area than the elliptical opening OPb portion, the adhesive film 340B may be in the form of a sheet including the elliptical opening OPb. The adhesive film 340b may correspond to the optical path block 330a of FIG. 5A above. Specifically, light collected through the convex microlens 332 of the optical path block 330a of FIG. 5A may pass through the opening OPb of the adhesive film 340b and may be incident on the optical coupler 314 of the PIC chip 310.

Referring to FIG. 6C, in the OEU package 300 of the semiconductor package 1000 of an embodiment, the adhesive film 340c may include a trapezoidal opening OPc formed in a central portion of the adhesive film 340c. The adhesive film 340c may still have a ring shape due to the presence of the trapezoidal opening OPc. However, in the adhesive film 340c, since the film portion occupies a wider area than the trapezoidal opening OPc portion, the adhesive film 340c is in the form of a sheet including the trapezoidal opening OPc. The adhesive film 340c may correspond to the optical path block 330a of FIG. 5A above. Specifically, light collected through the convex microlens 332 of the optical path block 330a of FIG. 5A may pass through the opening OPc of the adhesive film 340c and may be incident on the optical coupler 314 of the PIC chip 310.

Referring to FIG. 6D, in the OEU package 300 of the semiconductor package 1000 of an embodiment, an adhesive film 340d may include a rhombic opening OPd formed in a central portion of the adhesive film 340d. The adhesive film 340d may still have a ring shape due to the presence of the rhombic opening OPd. However, in the adhesive film 340d, since the film portion occupies a wider area than the rhombic opening OPd portion, the adhesive film 340d may be in the form of a sheet including the rhombic opening OPd. The adhesive film 340d may correspond to the optical path block 330a of FIG. 5A above. Specifically, light collected through the convex microlens 332 of the optical path block 330a of FIG. 5A may pass through the rhombic opening OPd of the adhesive film 340d and may be incident on the optical coupler 314 of the PIC chip 310. On the other hand, in the case of the rhombic opening OPd, when the adhesive film 340d is thick, the angle may be adjusted so that light is optimally passed along the path of incident light.

The shape of the opening has been described in terms of a circular shape, an elliptical shape, a trapezoidal shape, and a rhombic shape, but the shape of the opening is not limited thereto. For example, based on the thickness of the adhesive film and the path of incident light, the opening may have another polygonal shape.

Referring to FIG. 6E, in the OEU packages 300 of the semiconductor package 1000 of an embodiment, an adhesive film 340e may include openings OPe arranged in an array structure. The adhesive film 340e may have a ring shape with respect to each of the openings OPe. However, in the adhesive film 340e, since the film portion occupies a wider area than the opening OPe portion, the adhesive film 340e may be in the form of a sheet including the openings OPe. The adhesive film 340e may correspond to the optical path block 330b of FIG. 5B above. Accordingly, the openings OPe may be arranged in a 2 by 3 array structure. Specifically, light collected through each of the microlenses 332a of the optical path block 330b of FIG. 5B may pass through the corresponding openings OPe of the adhesive film 340e and may be incident on the optical coupler 314 of the PIC chip 310. In addition, when the microlenses 332a of the optical path block 330b are arranged in an array structure other than the 2 by 3 array structure, correspondingly, the openings OPe of the adhesive film 340e may also be arranged in another array structure. In addition, each of the openings OPe of the adhesive film 340e is not limited to a circular shape and may have various shapes such as an elliptical shape, a trapezoidal shape, and a rhombic shape, as shown in FIGS. 6B-6D.

Referring to FIG. 6F, in the OEU package 300 of the semiconductor package 1000 of an embodiment, the adhesive film 340f may include openings OPf arranged in a concentric structure. For example, the openings OPf may include one central opening and five outer openings surrounding the central opening. The adhesive film 340f may have a ring shape with respect to each of the openings OPf. However, in the adhesive film 340f, since the film portion occupies a wider area than the opening OPf portion, the adhesive film 340f may be in the form of a sheet including the openings OPf. The adhesive film 340f may correspond to the optical path block 330c of FIG. 5C above. Specifically, light collected through each of the microlenses 332b of the optical path block 330c of FIG. 5C may pass through the corresponding openings OPf of the adhesive film 340f and may be incident on the optical coupler 314 of the PIC chip 310. In addition, each of the openings OPf of the adhesive film 340f is not limited to a circular shape and may have various shapes, such as an elliptical shape, a trapezoidal shape, and a rhombic shape, as shown in FIGS. 6B-6D.

The structures of various shapes of adhesive films, including the rectangular ring shape of FIG. 4A, have been described. However, the structure of the adhesion film is not limited thereto. For example, the adhesive film may have more diverse structures under the condition that the optical path block 330 is adhered to a uniform height and at least one opening through which light can pass is provided.

FIGS. 7A and 7B are a plan view and a cross-sectional view, respectively, of the semiconductor package according to an embodiment, wherein FIG. 7B is a cross-sectional view of the semiconductor package of FIG. 7A taken along a line III-III’ of FIG. 7A. Descriptions are given with reference to FIGS. 1-2B together. Descriptions that are substantially the same as those given with reference to FIGS. 1-6F may be briefly given or omitted.

Referring to FIGS. 7A and 7B, a semiconductor package 1000a of an embodiment may be different from the semiconductor package 1000 of FIG. 2B by including an interposer 200a and partial OEUs 300a. Specifically, the semiconductor package 1000a of an embodiment may include the package substrate 100, an interposer 200a, partial OEUs 300a, the first semiconductor device 400, the second semiconductor devices 500, and the sealant 600. The package substrate 100, the first semiconductor device 400, the second semiconductor devices 500, and the sealant 600 may be the same as those in the semiconductor package 1000 described with reference to FIGS. 1-2B.

In the semiconductor package 1000a of an embodiment, the interposer 200a may include a Si-interposer. Specifically, the interposer 200a may include a body layer 201, an active layer 210, and through electrodes 220. The body layer 201 may include Si. The active layer 210 may be disposed on the body layer 201 and may include optical elements and wires. The optical elements may correspond to optical elements of the PIC chip. For example, the optical elements may include a light source, an optical waveguide, a passive circuit, an optical-to-current converter, or the like. In FIG. 7B, only the optical coupler 214, which is one of the passive circuits, is shown for convenience of explanation.

The through electrodes 220 may extend through the body layer 201. Since the body layer 201 includes Si, the through electrode 220 may correspond to a TSV. The through electrode 220 may connect the wiring of the active layer 210 to the first connection terminal 250 on the bottom surface of the body layer 201.

The partial OEU 300a may include an EIC chip 320 and an optical path block 330. The EIC chip 320 and the optical path block 330 may be separately mounted on the interposer 200a. Specifically, the EIC chip 320 may be mounted on the interposer 200a through internal connection terminals 325. The optical path block 330 may also be attached to the interposer 200a by the adhesive film 340 (see FIG. 3). The adhesive film 340 may include at least one opening through which light can pass, as described with reference to FIGS. 4A-4C and 6A-6F. Other details of the EIC chip 320 and the optical path block 330 may be the same as those described with reference to FIGS. 1-3.

For reference, when a structure including a PIC chip, an EIC chip, and an optical path block is called an OEU, the partial OEU 300a is a term that refers to a structure with the PIC chip omitted. In addition, since the partial OEU 300a is not a package structure sealed by the internal sealant, the partial OEU 300a is referred to as the partial OEU 300a rather than a partial OEU package.

In the semiconductor package 1000a of an embodiment, as the interposer 200a includes optical elements of the PIC chip, the interposer 200a may be referred to as a photonic interposer. The function of the interposer 200a may not differ significantly from the interposer 200 of the semiconductor package 1000 of FIG. 2B, except that the optical elements of the PIC chip may be arranged in the active layer 210 of the interposer 200a. For example, the partial OEU 300a, the first semiconductor device 400, and the second semiconductor devices 500 may be mounted on the interposer 200 and may be electrically connected to the package substrate 100 by the interposer 200. In addition, the interposer 200 may mediate signal transmission between the first semiconductor device 400 and the second semiconductor devices 500, signal transmission between the semiconductor devices (e.g., the first semiconductor device 400 and the second semiconductor devices 500) and the partial OEU 300a, and signal, power, and ground transmission between the partial OEU 300a, the first semiconductor device 400, or the second semiconductor device 500 and the package substrate 100.

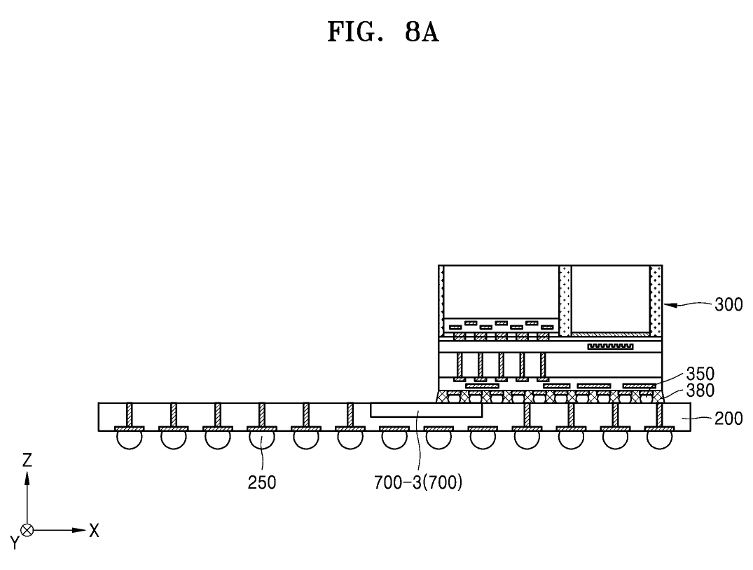

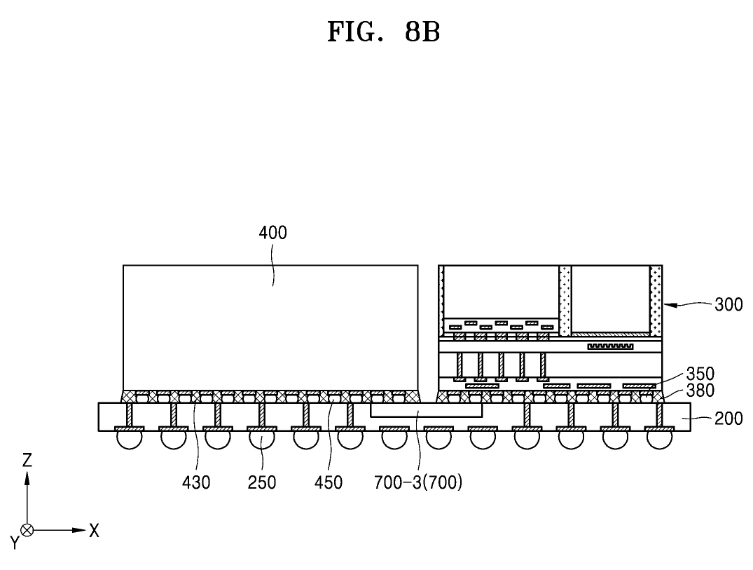

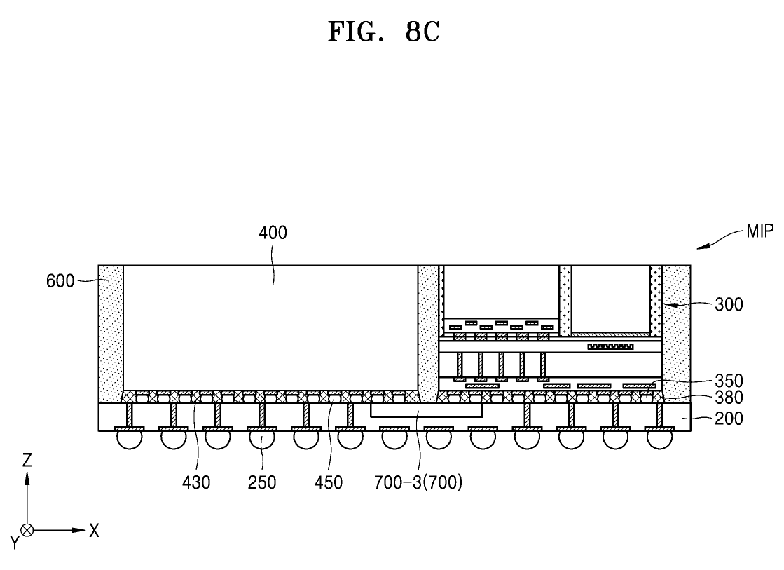

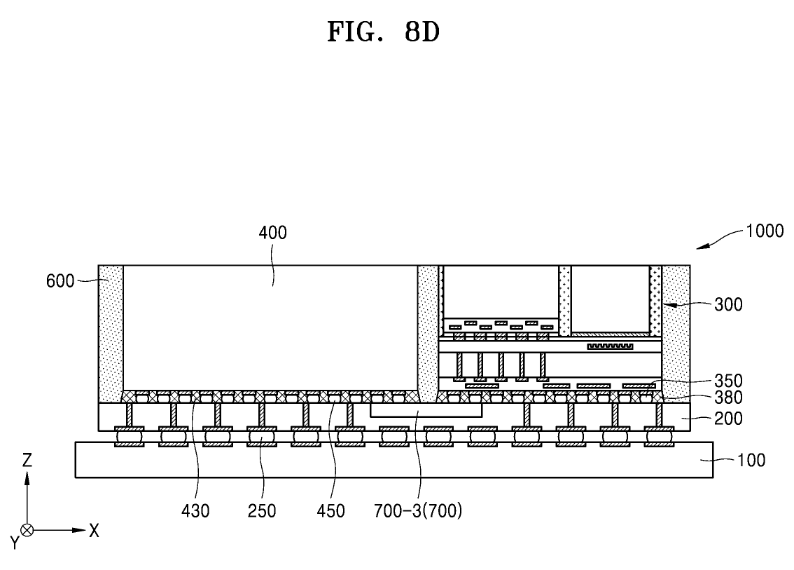

FIGS. 8A-8D are schematic cross-sectional views illustrating a process of a method of manufacturing the semiconductor package, according to an embodiment. Descriptions are given with reference to FIGS. 1-2B together. Descriptions that are substantially the same as those given with reference to FIGS. 1-7B may be briefly given or omitted.

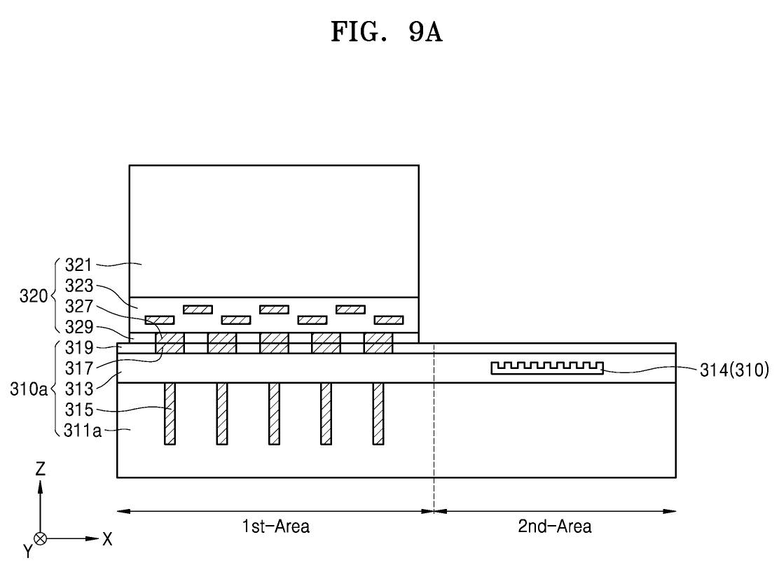

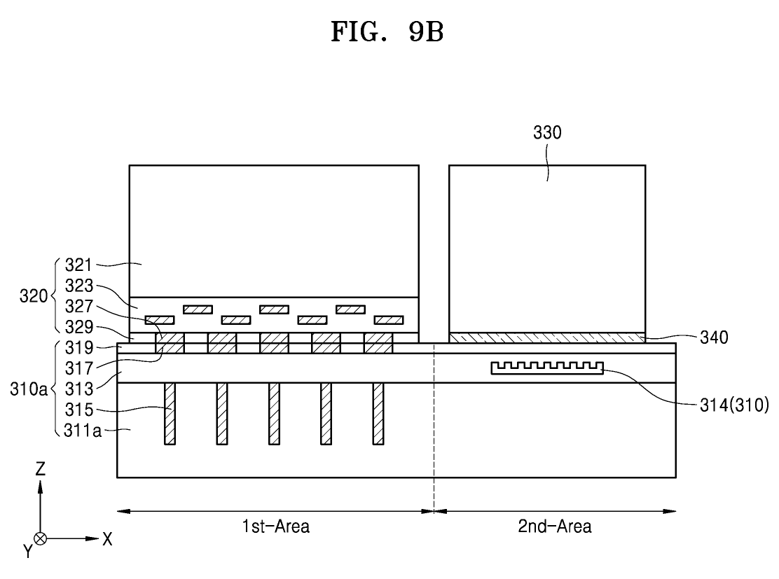

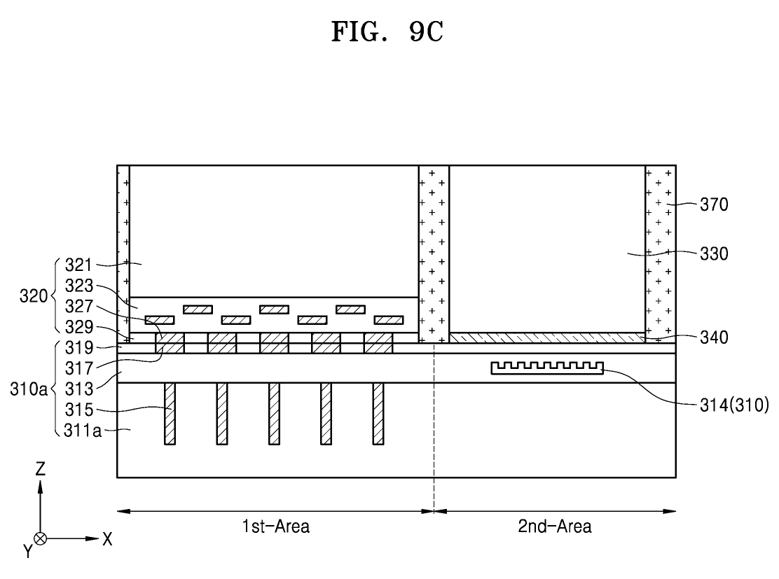

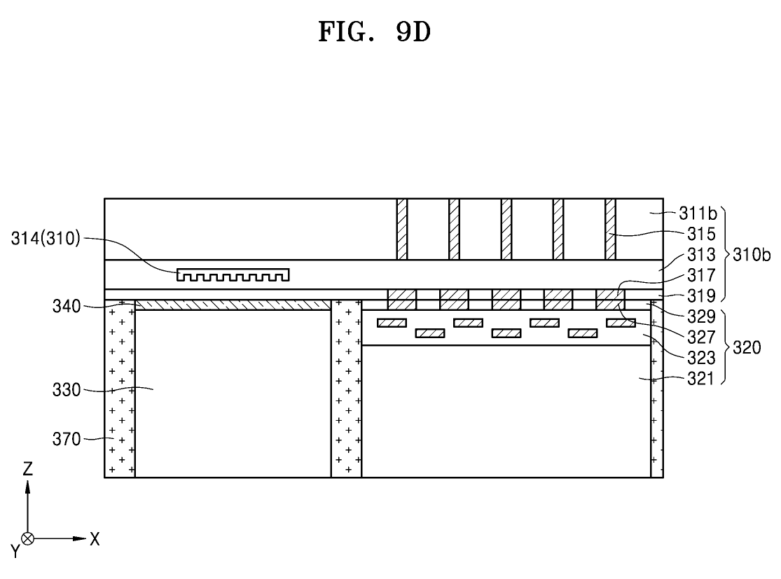

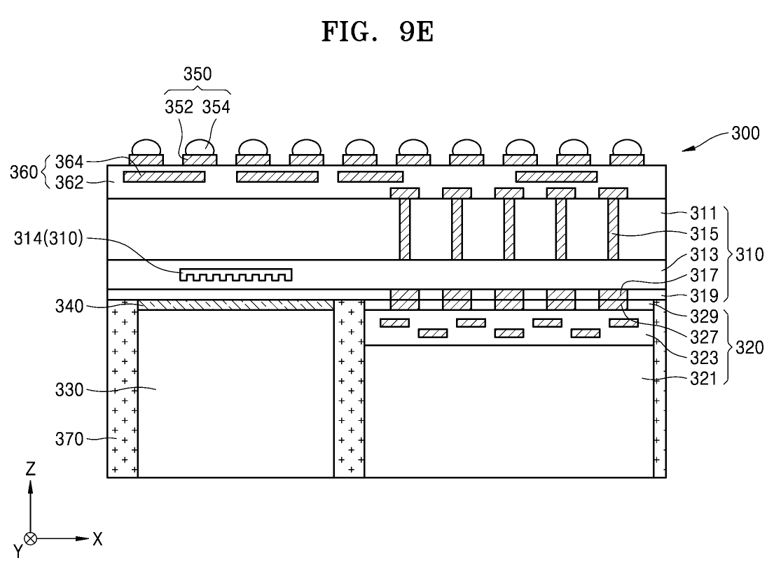

Referring to FIG. 8A, in the method of manufacturing the semiconductor package of an embodiment, first, the OEU package 300 may be manufactured, and the OEU package 300 may be mounted on the interposer 200 by the second connection terminals 350. The underfill 380 may fill the gap between the OEU package 300 and the interposer 200. In some embodiments, an adhesive layer may be arranged instead of the underfill 380. In addition, when the sealant 600 is performed in the MUF process, the underfill may be omitted. The interposer 200 and the OEU package 300 may be the same as those in the semiconductor package 1000 described with reference to FIGS. 1-2B. The process of manufacturing the OEU package 300 is described in more detail with reference to FIGS. 9A-9E.

Referring to FIG. 8B, after mounting the OEU package 300, the first semiconductor device 400 may be mounted on the interposer 200 by the third connection terminals 450. The underfill 430 may fill the gap between the first semiconductor device 400 and the interposer 200. The underfill 430 may be omitted or replaced with an adhesive layer. On the other hand, when the first semiconductor device 400 is mounted, the second semiconductor device 500 may also be mounted on the interposer 200 by the fourth connection terminal 550. The first semiconductor device 400 and the second semiconductor device 500 may be mounted in any order. The first semiconductor device 400 and the second semiconductor device 500 may be the same as those in the semiconductor package 1000 described with reference to FIGS. 1-2B.

Referring to FIG. 8C, after mounting the first semiconductor device 400 and the second semiconductor device 500, a sealant 600 may be formed on the interposer 200 to at least partially surround (e.g., seal) the OEU package 300, the first semiconductor device 400, and the second semiconductor device 500. The sealant 600 may cover the side surfaces of the OEU package 300, the first semiconductor device 400, and the second semiconductor device 500 and may fill the gap between the OEU package 300 and the first semiconductor device 400 and between the first semiconductor device 400 and the second semiconductor device 500. On the other hand, when the underfill 380, 430, or 530 is arranged between the OEU package 300, the first semiconductor device 400, or the second semiconductor devices 500 and the interposer 200, the sealant 600 may cover the side surfaces of the underfill 380, 430, or 530. The sealant 600 may be the same as that in the semiconductor package 1000 described with reference to FIGS. 1-2B. A molded interposer package MIP may be manufactured through the formation of the sealant 600.

Referring to FIG. 8D, after the formation of the molded interposer package MIP, the molded interposer package MIP may be mounted on the package substrate 100 by the first connection terminals 250. The package substrate 100 may be the same as that in the semiconductor package 1000 described with reference to FIGS. 1-2B. The semiconductor package 1000 may be completed by mounting the molded interposer package MIP. For example, the semiconductor package 1000 may correspond to the semiconductor package 1000 of FIG. 2B.

FIGS. 9A-9E are cross-sectional views illustrating a process of manufacturing the OEU package in more detail, in the operation of mounting the OEU package of FIG. 8A. Descriptions are given with reference to FIGS. 1-2B together. Descriptions that are substantially the same as those given with reference to FIGS. 1-8D may be briefly given or omitted.

Referring to FIG. 9A, in the method of manufacturing the semiconductor package of an embodiment, the process of manufacturing the OEU package 300 may include mounting the EIC chip 320 on a first area of a first initial PIC chip 310a by the HCB. In some embodiments, the EIC chip 320 may be mounted on the first initial PIC chip 310a by a fine connection terminal. The first initial PIC chip 310a may be in a wafer state. For example, the wafer may include a plurality of first initial PIC chips 310a, and a plurality of EIC chips 320 may be mounted on the corresponding first initial PIC chips 310a. FIG. 9A shows only one first initial PIC chip 310a for convenience of explanation.

The first initial PIC chip 310a may be thicker than the completed PIC chip 310. For example, a substrate 311a of the first initial PIC chip 310a may be thicker than the substrate 311 of the PIC chip 310 that is completed. Accordingly, the through electrodes 315 may not be exposed from the bottom surface of the substrate 311a. Other details of the EIC chip 320 and the first initial PIC chip 310a may be the same as those in the OEU package 300 described with reference to FIG. 3.

Referring to FIG. 9B, after mounting the EIC chip 320, the optical path block 330 may be attached onto a second area of the first initial PIC chip 310a by the adhesive film 340. The adhesive film 340 may include at least one opening through which light can pass. More specifically, the adhesive film 340 may be disposed on the first initial PIC chip 310a, and may have a structure in which an opening in a top surface of the adhesive film 340 corresponds to the optical coupler of the first initial PIC chip 310a. Then, the optical path block 330 may be attached onto the adhesive film 340 such that the outer portion of the bottom surface of the optical path block 330 is adhered to the adhesive film 340. On the other hand, in some embodiments, after the adhesive film 340 is arranged, the opening of the adhesive film 340 may be filled with a transparent gap-fill layer, and then the optical path block 330 may be attached to the adhesive film 340 and the gap-fill layer.

The plurality of optical path blocks 330 may be attached on the corresponding first initial PIC chips 310a. The optical path block 330 and the adhesive film 340 may be the same as those in the OEU package 300 described with reference to FIG. 3 and the adhesive films described with reference to FIGS. 4A-4C and 6A-6F.

Referring to FIG. 9C, after attaching the optical path block 330, the EIC chip 320 and the optical path blocks 330 may be sealed by an internal sealant 370a on the first initial PIC chip 310a. The internal sealant 370a having a wafer size may seal the plurality of EIC chips 320 and optical path blocks 330 on the first initial PIC chips 310a at a same time. The internal sealant 370a may be the same as that in the OEU package 300 described with reference to FIG. 3.

Referring to FIG. 9D, after forming the internal sealant 370a, the first initial PIC chip 310a and the structures thereon may be turned over, and part of the back surface of the substrate 311a of the first initial PIC chip 310a may be removed through a back-grinding process. After the back-grinding process, the first initial PIC chip 310a may form a second initial PIC chip 310b. The second initial PIC chip 310b may also be in a wafer state. On the other hand, in the second initial PIC chip 310b, the through electrodes 315 may be exposed from the back surface of the substrate 311b.

Referring to FIG. 9E, after the second initial PIC chip 310b is formed, an initial RDL and the second connection terminals 350 may be formed on the back surface of the second initial PIC chip 310b. In some embodiments, the second connection terminals 350 may be formed after individualization of the initial RDL. The initial RDL may have a wafer size and may be formed on the back surface of the entire second initial PIC chip 310b. The OEU package 300 may then be completed by individualizing the initial RDL, the second initial PIC chip 310b, and the structures thereon through a sawing process. The OEU package 300 may correspond to, for example, the OEU package 300 of FIG. 3.

According to some embodiments of the present disclosure, a manufacturing method of a semiconductor package may include: manufacturing an OEU package including a PIC chip, an EIC chip on the PIC chip, and an optical path block adjacent to the EIC chip and attached to the PIC chip through an adhesive film; mounting the OEU package on a package substrate; and mounting a memory device and a logic device on the package substrate adjacent to the OEU package, wherein the adhesive film includes at least one opening that is configured to pass light.

According to an embodiment, the manufacturing the OEU package may include preparing the PIC chip, stacking the EIC chip on a first area of the PIC chip, and attaching the optical path block onto a second area of the PIC chip such that the optical path block is adjacent to the EIC chip.

According to an embodiment, the adhesive film may have a ring shape including at least one open hole formed in a central portion of the adhesive film, the ring shape surrounding an outer portion of a bottom surface of the optical path block.

According to an embodiment, the PIC chip may include a substrate; an active layer on the substrate; an optical coupler in the second area of the PIC chip, in the active layer. The attaching the optical path block may include arranging the adhesive film on the PIC chip so that the at least one opening overlaps with the optical coupler. The optical path block may be attached onto the adhesive film such that an outer portion of the bottom surface of the optical path block is adhered to the adhesive film.

According to an embodiment, a through electrode may be in the substrate, in the first area of the PIC chip. The stacking the EIC chip may include stacking the EIC chip on the active layer, above the first area of the PIC chip, by hybrid copper bonding (HCB).

According to an embodiment, before the attaching of the optical path block, the at least one hole may be filled with a transparent gap-fill layer.

According to an embodiment, after the attaching of the optical path block, the method may further include forming a sealant on the PIC chip and at least partially surrounding the EIC chip and the optical path block.

According to an embodiment, the adhesive film may include any one from among an absorbent material, a reflective material, and a die attach film (DAF).

According to an embodiment, the optical path block may include any one from among glass, silicon (Si), silicon oxide (SiO₂), and a transparent polymer.

According to an embodiment, a microlens may be on at a bottom surface of the optical path block or a top surface of the optical path block, and the at least one opening may overlap with the at least one microlens.

While non-limiting example embodiments have been particularly described with reference to the accompanying drawings, it will be understood that various changes in form and details may be made therein without departing from the spirit and scope of the present disclosure.

What is claimed is:

1. A semiconductor package comprising:
a photonic integrated circuit (PIC) chip;
an electronic integrated circuit (EIC) chip on the PIC chip in a first direction;
an optical path block adjacent to the EIC chip in a second direction intersecting the first direction; and
an adhesive film that attaches the optical path block to the PIC chip in the first direction,
wherein the adhesive film includes at least one opening that is configured to pass light.

2. The semiconductor package of claim 1, wherein the adhesive film comprises a ring shape, and the at least one opening is in a central portion of the ring shape.

3. The semiconductor package of claim 1, wherein the adhesive film comprises an absorbent material or a reflective material.

4. The semiconductor package of claim 1, wherein the adhesive film comprises a die attach film (DAF).

5. The semiconductor package of claim 1, further comprising a transparent gap-fill layer in the at least one opening of the adhesive film.

6. The semiconductor package of claim 1, wherein the optical path block comprises any one from among glass, silicon (Si), silicon oxide (SiO₂), and a transparent polymer.

7. The semiconductor package of claim 1, wherein the PIC chip comprises:
a substrate;
an active layer on the substrate;
an optical coupler in the active layer, and overlapping with the optical path block in the first direction, and
a through electrode in the substrate, and overlapping with the EIC chip in the first direction.

8. The semiconductor package of claim 1, further comprising at least one microlens at a bottom surface of the optical path block or a top surface of the optical path block, and the at least one opening overlaps with the at least one microlens in the first direction.

9. The semiconductor package of claim 1, further comprising a sealant on the PIC chip and at least partially surrounding the optical path block and the EIC chip.

10. The semiconductor package of claim 1, wherein the at least one opening comprises a circular, elliptical, or polygonal shape.

11. The semiconductor package of claim 1, further comprising a redistribution layer on a bottom surface of the PIC chip.

12. A semiconductor package comprising:
a photonic integrated circuit (PIC) chip comprising:
a substrate comprising a through electrode; and
an active layer on the substrate in a first direction, the active layer comprising an optical coupler;
an electronic integrated circuit (EIC) chip on the PIC chip in the first direction, and overlapping with the through electrode in the first direction;
an optical path block adjacent to the EIC chip in a second direction intersecting the first direction, and overlapping with the optical coupler in the first direction;
an adhesive film that attaches the optical path block to the PIC chip in the first direction;
a sealant on the PIC chip and at least partially surrounding the EIC chip and the optical path block; and
a connection terminal on a bottom surface of the PIC chip,
wherein the adhesive film comprises a ring shape on an outer portion of a bottom surface of the optical path block.

13. The semiconductor package of claim 12, wherein the adhesive film comprises a die attach film (DAF) including an opening in a central portion of the DAF, and the opening is empty or includes a transparent gap-fill layer.

14. The semiconductor package of claim 12, further comprising a microlens at the bottom surface of the optical path block or a top surface of the optical path block, and the opening overlaps with the microlens in the first direction.

15. A semiconductor package comprising:
a package substrate;
an optical engine unit (OEU) package on the package substrate in a first direction;
a logic device on the package substrate in the first direction, and adjacent to the OEU package; and
a memory device adjacent to the logic device, and on the package substrate in the first direction,
wherein the OEU package comprises:
a photonic integrated circuit (PIC) chip;
an electronic integrated circuit (EIC) chip on the PIC chip in the first direction;
an optical path block adjacent to the EIC chip in a second direction intersecting the first direction; and
an adhesive film that attaches the optical path block to the PIC chip in the first direction, and
wherein the adhesive film includes at least one opening that is configured to pass light.

16. The semiconductor package of claim 15, wherein the adhesive film comprises a ring shape, the at least one opening is in a central portion of the ring shape, and the at least one opening is empty or includes a transparent gap-fill layer.

17. The semiconductor package of claim 15, wherein the adhesive film comprises a die attach film (DAF) that includes the at least one opening in a center portion of the DAF.

18. The semiconductor package of claim 15, wherein the PIC chip comprises:
a substrate;
an active layer on the substrate;
an optical coupler in the active layer, and overlapping with the optical path block in the first direction; and
a through electrode in the substrate, and overlapping with the EIC chip in the first direction.

19. The semiconductor package of claim 15, wherein the OEU package further comprises:
a sealant on the PIC chip and at least partially surrounding the EIC chip and the optical path block on the PIC chip; and
a connection terminal on a bottom surface of the PIC chip, the connection terminal connecting the OEU package and the package substrate.

20. The semiconductor package of claim 15, further comprising an interposer on the package substrate in the first direction,
wherein the OEU package, the logic device, and the memory device are on the interposer in the first direction.
